(19) United States
(12) Patent Application Publication
(10) Pub. No.: US 2014/0183434 A1
(43) Pub. Date: Jul. 3, 2014

(54) VARIABLE RESISTANCE MEMORY DEVICES AND METHODS OF FORMING THE SAME

(71) Applicant: SAMSUNG ELECTRONICS CO., LTD., Suwon-si (KR)

(72) Inventors: Hanjin LIM, Seoul (KR); Wonseok YOO, Hwaseong-si (KR); Insang JEON, Seoul (KR); Seokwoo NAM, Seongnam-si (KR); Kongsoo LEE, Hwaseong-gum (KR); Jaejong HAN, Seoul (KR)

(73) Assignee: SAMSUNG ELECTRONICS CO., LTD., Suwon-Si (KR)

(21) Appl. No.: 14/064,826

(22) Filed: Oct. 28, 2013

(30) Foreign Application Priority Data
Jan. 3, 2013 (KR) 10-2013-0000624

(51) Int. Cl. H01L 27/24; H01L 29/78; H01L 29/872

(52) U.S. Cl. CPC H01L 27/2463; H01L 29/872; H01L 29/7839
USPC 257/4; 257/475; 257/288

(57) ABSTRACT

Semiconductor devices, and methods of fabricating the same, include a metal-containing layer on a semiconductor layer, and a barrier-lowering portion between the metal-containing layer and the semiconductor layer. The barrier-lowering portion lowers a Schottky barrier height between the metal-containing layer and the semiconductor layer below a Schottky barrier height between a metal silicide layer and the semiconductor layer.

### CROSS-REFERENCE TO RELATED APPLICATIONS

This U.S. non-provisional patent application claims the benefit of priority under 35 U.S.C. §119 from Korean Patent Application No. 10-2013-0000624, filed on Jan. 3, 2013, in the Korean Intellectual Property Office, the entire contents of which are herein incorporated by reference.

### BACKGROUND

1. Field

Example embodiments of inventive concepts relate to semiconductor devices and methods of forming the same.

2. Description of Related Art

Next generation semiconductor memory devices are being developed for high performance and low power usage. Next generation semiconductor memory devices may, for instance, include a ferroelectric random access memory (FRAM), a magnetic random access memory (MRAM) and a phase change random access memory (PRAM). Materials constituting the next generation semiconductor memory devices may exhibit a varying resistance depending on a current or voltage applied thereto, and be able to maintain a resistance even when a current supply or a voltage supply is interrupted.

PRAM devices using phase changeable material are being studied because PRAM devices may have satisfactory operation speed and/or integration.

### SUMMARY

Example embodiments of inventive concepts relate to semiconductor devices and methods of forming the same.

Example embodiments of inventive concepts provide semiconductor devices with high operation speed.

Other example embodiments of inventive concepts provide methods of fabricating the semiconductor device.

According to example embodiments of inventive concepts, a semiconductor device may include a metal-containing layer on a semiconductor layer, and a barrier-lowering portion between the semiconductor layer and the metal-containing layer. The barrier-lowering portion lowers a Schottky barrier height (SBH) between the metal-containing layer and the semiconductor layer below an SBH between a metal silicide layer and the semiconductor layer.

In example embodiments, the semiconductor layer may be doped with P-type impurities and have an impurity concentration of 10²⁰ ions/cm³ or higher.

In example embodiments, the barrier-lowering portion may include a dopant within a surface of the semiconductor layer, and the dopant may include at least one element selected from the group consisting of aluminum, gallium, beryllium, fluorine, and platinum. A concentration of the at least one element ranges from about 10¹⁹ atoms/cm³ to about 10²⁰ atoms/cm³. The device may further include a metal silicide layer between the barrier-lowering portion and the metal-containing layer.

In example embodiments, the barrier-lowering portion may include a high-k dielectric material, and the high-k dielectric material may have a dielectric constant higher than a dielectric constant of silicon oxide. The barrier-lowering portion may further include a thermal oxide layer between the high-k dielectric and the semiconductor layer. The thermal oxide layer may have a thickness of about 5-10 Å. For example, the high-k dielectric may be formed of aluminum oxide and have a thickness of 10 Å or less. Alternatively, the high-k dielectric material may be formed of titanium oxide and may have a thickness of 60 Å or less.

In example embodiments, the device may further include a substrate below the semiconductor layer, a word line within the substrate, a bit line on the metal-containing layer and crossing the word line, and a variable resistance pattern between the metal-containing layer and the bit line. The semiconductor layer may be configured to form a pn-junction diode between the word line and the metal-containing layer. For example, the device may further include a first interlayered insulating layer covering the substrate and including a first hole. The semiconductor layer, the barrier-lowering portion, and the metal-containing layer may be within the first hole, and the barrier-lowering portion may include a high-k dielectric extending along an inner sidewall of the first hole. Alternatively, the device may further include a first interlayered insulating layer covering the substrate, and a second interlayered insulating layer on the first interlayered insulating layer. The semiconductor layer and the metal-containing layer may be within the first and second interlayered insulating layers, respectively, and the barrier-lowering portion may include a high-k dielectric extending between the first and second interlayered insulating layers.

In example embodiments, the device may further include a gate electrode on the semiconductor layer, and a metal silicide layer between the metal-containing layer and the semiconductor layer. The semiconductor layer may be a semiconductor substrate, the metal-containing layer may correspond to a contact plug adjacent to the gate electrode, the barrier-lowering portion may include a dopant within a surface of the semiconductor layer, and the dopant may include an ion of at least one element selected from the group consisting of boron, aluminum, gallium, beryllium, fluorine, and platinum.

In example embodiments, the device may further include a gate electrode on the semiconductor layer. The semiconductor layer may be a semiconductor substrate, the metal-containing layer may correspond to a contact plug adjacent to the gate electrode, and the barrier-lowering portion may include a high-k dielectric extending to cover the gate electrode.

According to example embodiments, a semiconductor device includes a Schottky barrier contact including a barrier-lowering portion crossing the Schottky barrier contact along a metal-semiconductor junction of the Schottky barrier contact, wherein the barrier-lowering portion reduces a Schottky barrier height (SBH) of the metal-semiconductor junction to lower than about 0.6 eV.

In example embodiments, the semiconductor device may further include an ohmic layer between the barrier-lowering portion and a metal-containing layer of the Schottky barrier contact. The ohmic layer may include a metal silicide, the metal-containing layer may include a metal nitride, and the barrier-lowering portion may include at least one selected from an aluminum dopant, a gallium dopant, a beryllium dopant, a fluorine dopant and a platinum dopant.

In example embodiments, the semiconductor device may further include a gate electrode on a substrate, wherein the barrier-lowering portion is at least partially recessed within an interlayered insulating layer over the substrate, a source and drain region in the substrate adjacent to the gate electrode, a contact plug over the source and drain region, and an ohmic layer in contact with the contact plug. The barrier-lowering portion may be under the contact plug and may have a width greater than or equal to a width of the contact plug. The Schottky barrier contact may collectively include the source and drain region, the barrier-lowering portion, the contact plug, and the ohmic layer.

The barrier-lowering portion may consist of a high dielectric layer over a thermal oxide layer.

The Schottky barrier contact may further include a diffusion barrier layer and a semiconductor layer, collectively, forming the metal-semiconductor junction. The diffusion barrier layer may be a metal nitride layer, and the barrier-lowering portion may include a dopant made of at least one element selected from the group consisting of aluminum, gallium, beryllium, fluorine, and platinum.

According to example embodiments of inventive concepts, a method of fabricating a semiconductor device may include forming a metal-containing layer on a semiconductor layer, and forming a barrier-lowering portion between the semiconductor layer and the metal-containing layer.

In example embodiments, the forming of the barrier-lowering portion may include forming a metal silicide layer on the semiconductor layer, before the formation of the metal-containing layer, and performing an ion implantation process to dope a surface of the semiconductor layer below the metal silicide layer with at least one element selected from the group consisting of boron, aluminum, gallium, beryllium, fluorine, and platinum.

In other example embodiments, the forming of the barrier-lowering portion may be performed before the formation of the metal-containing layer. Here, the formation of the barrier-lowering portion may include forming a thermal oxide layer and a high-k dielectric on the semiconductor layer.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view illustrating a semiconductor device according to example embodiments of inventive concepts.

FIG. 2 is a sectional view illustrating a semiconductor device according to example embodiments of inventive concepts.

FIG. 3A is a circuit diagram illustrating a memory cell array of a variable resistance memory device according to example embodiments of inventive concepts.

FIG. 3B is a layout view illustrating a semiconductor device according to the example embodiments of inventive concepts.

FIG. 3C is a sectional view taken along line A-A of FIG. 3B to describe a semiconductor device according to the example embodiments of inventive concepts.

FIGS. 4A through 4D are sectional views illustrating a process of fabricating a semiconductor device having a section shaped like the example embodiments shown in FIG. 3C.

FIG. 5 is a sectional view taken along line A-A of FIG. 3B to describe a semiconductor device according to example embodiments of inventive concepts.

FIGS. 6A and 6B are sectional views illustrating a process of fabricating a semiconductor device having a section shaped like the example embodiments shown in FIG. 5.

FIG. 7 is a sectional view taken along line A-A of FIG. 3B to describe a semiconductor device according to example embodiments of inventive concepts.

FIGS. 8A through 8C are sectional views illustrating a process of fabricating a semiconductor device having a section shaped like the example embodiments shown in FIG. 7.

FIG. 9 is a sectional view illustrating a semiconductor device according to example embodiments of inventive concepts.

FIG. 10 is a sectional view illustrating a process of fabricating a semiconductor device having a section shaped like the example embodiments shown in FIG. 9.

FIG. 11 is a sectional view illustrating a semiconductor device according to example embodiments of inventive concepts.

FIG. 12 is a sectional view illustrating a process of fabricating a semiconductor device having a section shaped like the example embodiments shown in FIG. 11.

FIG. 13 is a block diagram illustrating an example of systems including a memory device according to example embodiments of inventive concepts.

FIG. 14 is a block diagram illustrating an example of memory cards including a memory device according to example embodiments of inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Various example embodiments will now be described more fully with reference to the accompanying drawings in which some example embodiments are shown. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “t will be understood that, if an element is another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Example embodiments of inventive concepts relate to semiconductor devices and methods of forming the same.

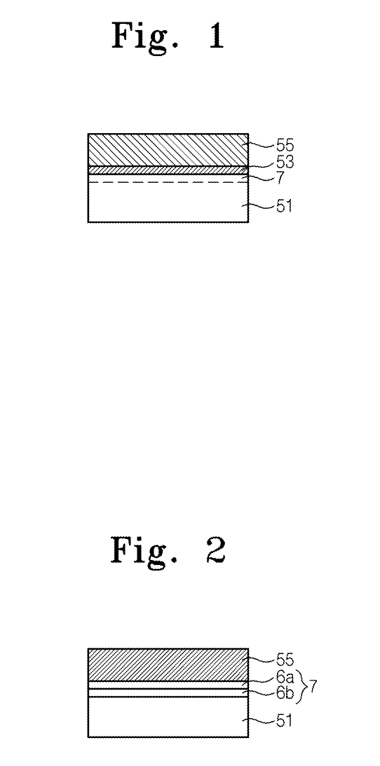

FIG. 1 is a sectional view illustrating a semiconductor device according to example embodiments of inventive concepts.

Referring to FIG. 1, a metal-containing layer 55 may be stacked on a semiconductor layer 51. The semiconductor layer 51 may be, for example, single crystalline silicon. The metal-containing layer 55 may be at least one of, for example, a metal layer or a metal nitride layer. A metal silicide layer 53 may be interposed between the semiconductor layer 51 and the metal-containing layer 55 to serve as an ohmic layer. A barrier-lowering portion 7 may be disposed between the metal silicide layer 53 and the semiconductor layer 51. Due to the presence of the barrier-lowering portion 7, it is possible to reduce a Schottky barrier height (SBH) between the metal-containing layer 55 and the semiconductor layer 51, compared with a Schottky barrier height between the metal silicide layer 53 and the semiconductor layer 51 that are in direct contact with each other. For example, the barrier-lowering portion 7 may be configured in such a way that the Schottky barrier height between the semiconductor layer 51 and the metal-containing layer 55 is lower than 0.6 eV. The formation of the barrier-lowering portion 7 may include doping a surface of the semiconductor layer 51 with at least one ion selected from the group consisting of aluminum, gallium, beryllium, fluorine, and platinum. For example, the barrier-lowering portion 7 may be doped with aluminum. The barrier-lowering portion 7 may be formed in such a way that a concentration of the element ranges from 10¹⁹ atoms/cm³ to 10²⁰ atoms/cm³. For example, the semiconductor layer 51 may be doped with P-type impurities. Here, in the semiconductor layer 51, a concentration of the P-type impurities may be about 10²⁰ ions/cm³ or higher. In the example embodiments, the barrier-lowering portion 7 may be positioned between the metal silicide layer 53 and the P-type semiconductor layer 51 to stabilize the metal silicide layer 53 and lower the Schottky barrier height. As the result of the lowering of the Schottky barrier height, it is possible to reduce an electric resistance between the metal-containing layer 55 and the semiconductor layer 51 and improve a current flow therebetween, and this makes it possible to improve an operation speed of the device.

The structure of FIG. 1 may be formed by the following method. An ion implantation process may be performed to the semiconductor layer 51 to dope the semiconductor layer 51 with P-type impurities. A metal layer may be deposited on the semiconductor layer 51, and a thermal treatment process may be performed to react the metal layer with the semiconductor layer 51 and thereby form the metal silicide layer 53. An unreacted portion of the metal layer, which is not used for the metal silicide layer 53, may be removed. An ion implantation process may be performed to form the barrier-lowering portion 7 in a top portion of the semiconductor layer 51 adjacent to the metal silicide layer 53. The ion implantation process for the barrier-lowering portion 7 may be performed using at least one element selected from the group consisting of boron, aluminum, gallium, beryllium, fluorine, and platinum.

FIG. 2 is a sectional view illustrating a semiconductor device according to example embodiments of inventive concepts.

Referring to FIG. 2, the barrier-lowering portion 7 may be interposed between the semiconductor layer 51 and the metal-containing layer 55. In the present example embodiments, the metal silicide layer may not be interposed between the semiconductor layer 51 and the metal-containing layer 55. The barrier-lowering portion 7 may include a high-k dielectric 6a having a dielectric constant is higher than that of the silicon oxide layer. The high-k dielectric 6a may be at least one of, for example, aluminum oxide, titanium oxide, or zirconium oxide. In the case where the high-k dielectric 6a is aluminum oxide, it may be formed to have a thickness of 10 Å or less. In the case where the high-k dielectric 6a is titanium oxide, it may be formed to have a thickness of 60 Å or less. The barrier-lowering portion 7 may further include a thermal oxide layer 6b that is disposed between the high-k dielectric 6a and the semiconductor layer 51. The thermal oxide layer 6b may be formed to have a thickness of about 5-10 Å. The high-k dielectric 6a and the thermal oxide layer 6b may form a dipole between the semiconductor layer 51 and the metal-containing layer 55, thereby lowering the Schottky barrier height therebetween. In this case, the barrier-lowering portion 7 makes it possible to lower the Schottky barrier height to about 0.2 eV or less. Except for this difference, the device may be configured to have substantially the same or similar features as that shown in FIG. 1.

The structure of FIG. 2 may be formed by the following method. An ion implantation process may be performed to the semiconductor layer 51 to dope the semiconductor layer 51 with P-type impurities. The high-k dielectric 6a may be deposited on the semiconductor layer 51. The deposition of the high-k dielectric 6a may include supplying oxygen gas as a source gas at a temperature higher than the room temperature. Oxygen to be supplied at the high temperature may be reacted with a surface of the semiconductor layer 51 to form the thermal oxide layer 6b, before the formation of the high-k dielectric 6a. The thermal oxide layer 6b may be formed to have a thickness of about 5-10 Å. After the thin formation of the thermal oxide layer 6b, the high-k dielectric 6a may be deposited. The metal-containing layer 55 may be formed on the high-k dielectric 6a.

### Experimental Example

(1) Comparative Group 1: a cobalt silicide layer and a titanium nitride layer were sequentially formed on a silicon layer that was doped to have a boron concentration of about 10²⁰ ions/cm³.

(2) Comparative Group 2: only a titanium nitride layer (i.e., without the cobalt silicide layer) was formed on a silicon layer that was doped to have a boron concentration of about 10²⁰ ions/cm³.

(3) Experimental Group 1: an aluminum oxide layer having a thickness of about 10 Å was formed on a silicon layer that was doped to have a boron concentration of about 10²⁰ ions/cm³. Here, a thermal oxide layer having a thickness of about 5 Å was formed between the aluminum oxide and the silicon layer. A titanium nitride layer was formed on the aluminum oxide layer.

(4) Experimental Group 2: a titanium oxide having a thickness of about 60 Å was formed on a silicon layer that was doped to have a boron concentration of about 10²⁰ ions/cm³. Here, a thermal oxide layer having a thickness of about 5 Å was formed between the titanium oxide and the silicon layer. A titanium nitride layer was formed on the titanium oxide layer.

In the comparative groups and the experimental groups, the titanium nitride layers had the same thickness. The following TABLE 1 shows the measurement results of the Schottky barrier height (SBH) between the titanium nitride layer and the silicon layer.

TABLE 1

| | Comparative | Comparative | Experimental | Experimental |
|---|---|---|---|---|
| | Group 1 | Group 2 | Group 1 | Group 2 |
| SBH | 1.13 eV | 1.21 eV | 1.05 eV | 0.69 eV |

As illustrated in Table 1, the Schottky barrier height can be lowered by the presence of the barrier-lowering portion.

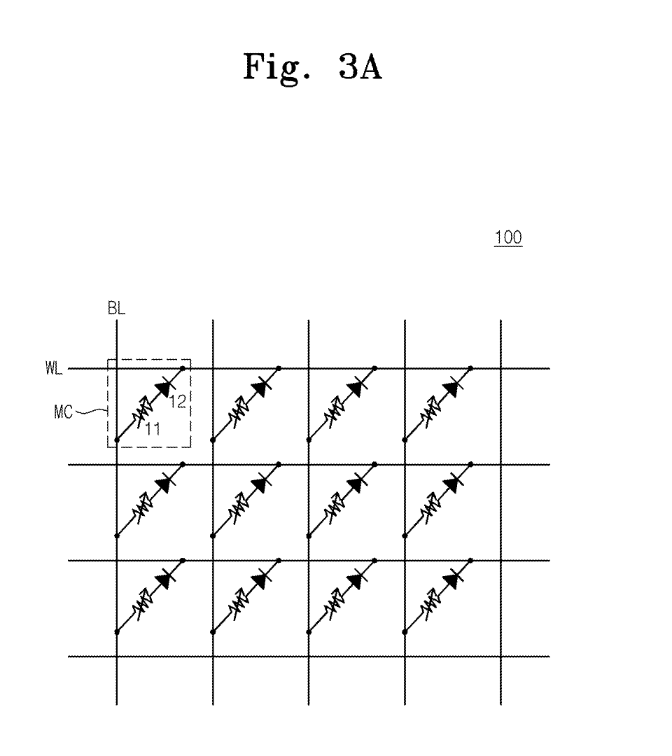

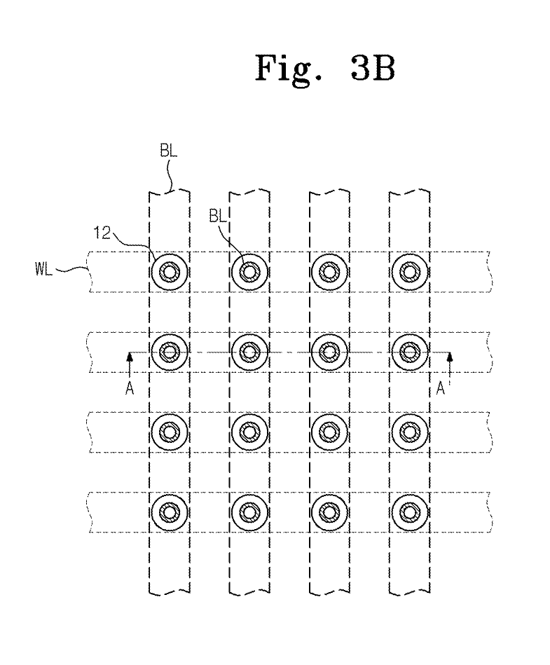

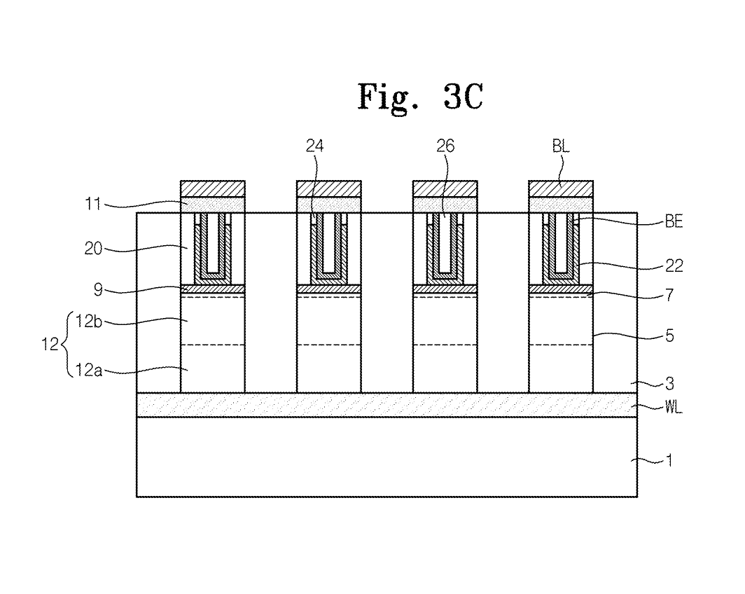

FIG. 3A is a circuit diagram illustrating a memory cell array of a variable resistance memory device according to example embodiments of inventive concepts.

Referring to FIG. 3A, the semiconductor device according to the example embodiments may be a variable resistance memory device 100 (e.g., a phase-change memory device). In the variable resistance memory device 100, a plurality of memory cells MC may be arranged to form a matrix structure. Each of the memory cells MC may include a variable resistance device 11 and a selection device 12. The variable resistance device 11 may be provided between a bit line BL and the selection device 12, and the selection device 12 may be provided between the variable resistance device 11 and a word line WL.

The variable resistance device 11 may include at least one of, for example, phase-changeable materials, ferroelectric materials, or magnetic materials. A data state of the variable resistance device 11 may be changed by an amount of current supplied through the bit line BL.

The selection device 12 may be provided between the variable resistance device 11 and the word line WL to connect them. A voltage applied to the word line WL may be used to control an amount or flow of electric current to be supplied to the variable resistance device 11 through the selection device 12. In example embodiments, the selection device 12 may constitute a pn-junction diode.

Hereinafter, the description that follows will refer to example embodiments in which a phase-changeable material is used for memory cells of the variable resistance device 11. But example embodiments of inventive concepts may not be limited thereto and be applied to realized Resistance Random Access Memory (RRAM), Ferroelectric RAM (FRAM), or Magnetic RAM (MRAM).

In the present example embodiments, the variable resistance device 11 may include a phase-changeable material having a resistance that can be changed by an amount of heat applied thereto. For example, depending on temperature and quenching time, the phase-changeable material may have two different crystal states: an amorphous state of high resistance and a crystal state of low resistance. The phase-changeable material may be heated by Joule's heat that is generated by an electric current supplied from the lower electrode. Joule's heat may be produced proportional to resistivity of the phase-changeable material and a supplying time of the electric current.

FIG. 3B is a layout view illustrating a semiconductor device according to the example embodiments of inventive concepts. FIG. 3C is a sectional view taken along line A-A of FIG. 3B to describe a semiconductor device according to the example embodiments of inventive concepts.

Referring to FIGS. 3B and 3C, a variable resistance memory device according to the present example embodiments may include a plurality of word lines WL provided parallel to each other on the substrate 1. The substrate 1 may be, for example, a semiconductor wafer doped with P-type impurities. A device isolation layer (not shown) may be provided in the substrate 1 to define active regions. The word lines WL may be, for example, N-type doped regions provided in the substrate 1. Alternatively, the word lines WL may be formed of conductive patterns. A plurality of bit lines BL may be provided parallel to each other over the word lines WL. The bit lines BL may be provided across the word lines WL. An interlayered insulating layer 3 may be provided between the bit lines BL and the word lines WL to cover the substrate 1. A selection device hole 5 may be formed in the interlayered insulating layer 3. For example, the selection device hole 5 may be formed at an intersection between the bit lines BL and the word lines WL. The selection device 12 may be provided in the selection device hole 5. In example embodiments, the selection device 12 may be a pn-junction diode. The selection device 12 may include a first semiconductor layer 12a and a second semiconductor layer 12b with opposite conductivity types. For example, the first semiconductor layer 12a may be doped with N-type impurities, while the second semiconductor layer 12b may be doped with P-type impurities. The second semiconductor layer 12b may correspond to the semiconductor layer 51 of the shown in FIG. 1. A metal silicide layer 9 may be provided on the selection device 12 in the selection device hole 5. The metal silicide layer 9 may serve as an ohmic layer. The metal silicide layer 9 may be, for example, a cobalt silicide layer. The barrier-lowering portion 7 may be disposed between the metal silicide layer 9 and the second semiconductor layer 12b. The barrier-lowering portion 7 may be configured to have the same features as the barrier-lowering portion 7 shown in FIG. 1.

Next, an insulating spacer 20 may be formed on the metal silicide layer 9 to cover a sidewall of the selection device hole 5. A diffusion barrier layer 22 may be formed to cover an inner sidewall of the insulating spacer 20 and a top surface of the metal silicide layer 9. The diffusion barrier layer 22 may be formed of a metal nitride layer (e.g., a titanium nitride layer). The diffusion barrier layer 22 may be shaped like a cup, in a sectional view. A second insulating gap-fill pattern 24 may be provided on a top surface of the diffusion barrier layer 22. A lower electrode BE may be formed to cover an inner sidewall and a bottom surface of the diffusion barrier layer 22 and the second insulating gap-fill pattern 24. The lower electrode BE may be formed of a metal layer (e.g., a layer of tungsten, or alternatively, a layer including tungsten, or alternatively, a layer consisting essentially of tungsten). The lower electrode BE may be formed to have a cup shape, in sectional view. The lower electrode BE may have atop surface that is coplanar with that of the second insulating gap-fill pattern 24. An inner space of the lower electrode BE may be filled with a first insulating gap-fill pattern 26.

The variable resistance pattern 11 may be provided on the lower electrode BE. The variable resistance pattern 11 may be formed of a compound containing at least two elements selected from the group consisting of Te, Se, Ge, Sb, Bi, Pb, Sn, Ag, As, S, Si, P, O, and C. The variable resistance pattern 11 may be in direct contact with the lower electrode BE. The bit line BL may be provided on the variable resistance pattern 11.

The variable resistance memory device according to the present example embodiments may include the barrier-lowering portion 7, and this makes it possible to increase on-current and improve a device operation.

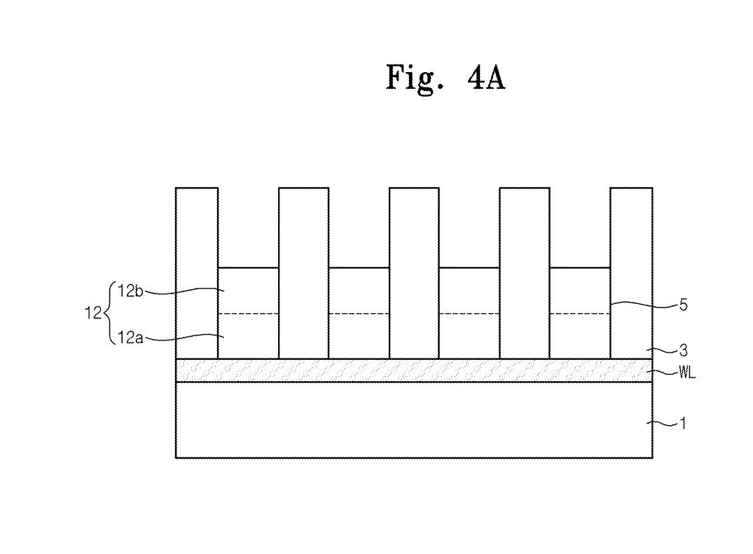

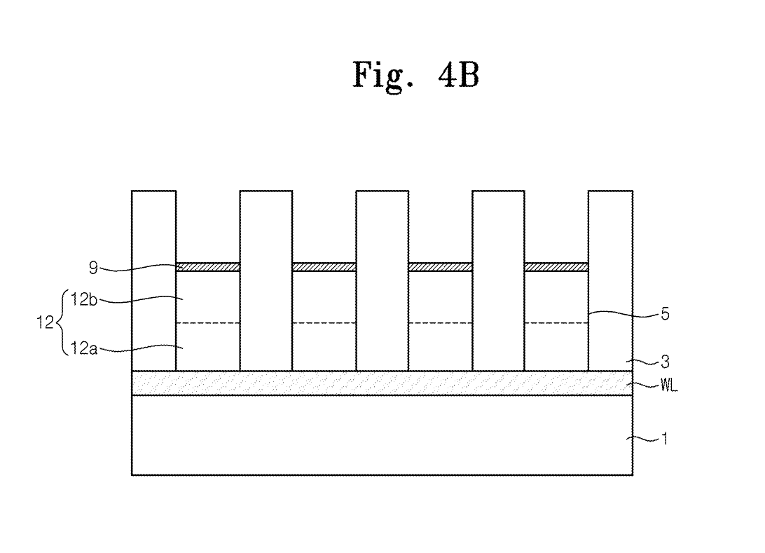

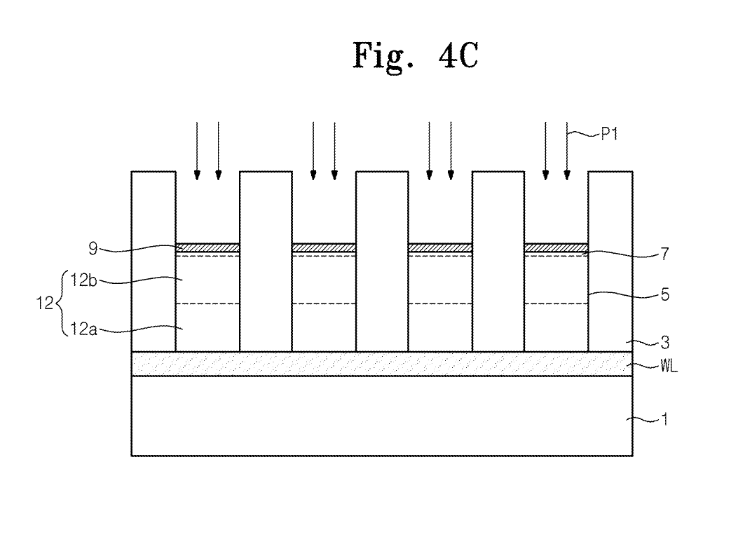

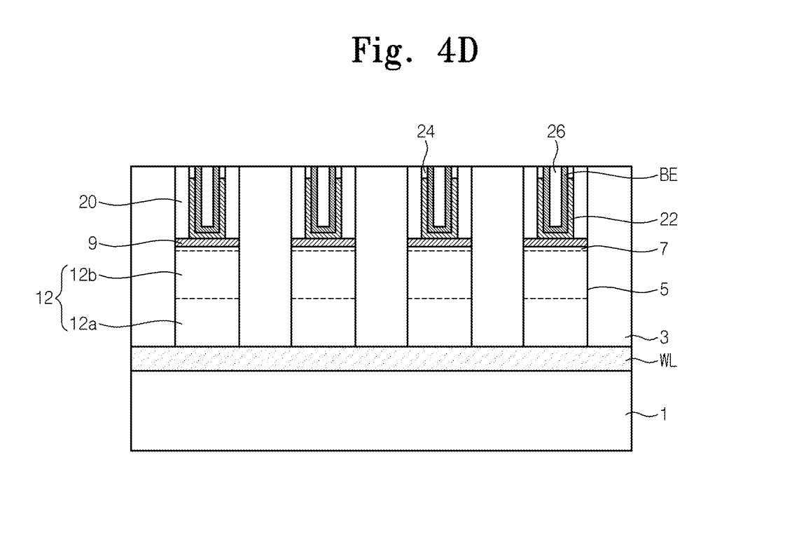

FIGS. 4A through 4D are sectional views illustrating a process of fabricating a semiconductor device having a section shaped like the example embodiments shown in FIG. 3C.

Referring to FIG. 4A, the substrate 1 of, for example, P-type may be provided. A device isolation layer (not shown) may be formed in the substrate 1 to define line-shaped active regions. A first ion implantation process may be performed to dope an exposed portion of the active region with, for example, N-type impurities and thereby form the word lines WL. The interlayered insulating layer 3 may be deposited on the substrate 1 and be patterned to form a plurality of selection device holes 5 that are spaced apart from each other. The selection device holes 5 may be formed to expose the word line WL. A selective epitaxial growth (SEG) process may be performed to form a semiconductor layer filling a lower portion of the selection device hole 5. A second ion implantation process may be performed to dope a lower portion of the semiconductor layer with, for example, N-type impurities and thereby form the first semiconductor layer 12a. A third ion implantation process may be performed to dope an upper portion of the semiconductor layer with, for example, P-type impurities and thereby form the second semiconductor layer 12b.

Referring to FIG. 4B, a metal layer (not shown) may be conformally deposited on the substrate 1, and be thermally treated to react the metal layer with the second semiconductor layer 12b and thereby form the metal silicide layer 9. An unreacted portion of the metal layer may be removed.

Referring to FIG. 4C, a fourth ion implantation process P1 may be performed to form the barrier-lowering portion 7 below the metal silicide layer 9. In example embodiments, at least one element selected from the group consisting of boron, aluminum, gallium, beryllium, fluorine, and platinum may be used for the fourth ion implantation process P1.

Referring to FIG. 4D, the insulating spacer 20 may be formed on the metal silicide layer 9 to cover the inner sidewall of the selection device hole 5. The diffusion barrier layer 22 may be formed to conformally cover an inner sidewall of the insulating spacer 20 and a top surface of the metal silicide layer 9. The lower electrode layer BE may be formed to conformally cover an inner sidewall and a bottom surface of the diffusion barrier layer 22. The first insulating gap fill layer 26 may be formed to fill an inner space of the lower electrode layer BE. A planarization etching process may be performed to remove the first insulating gap fill layer 26, the lower electrode layer BE, the diffusion barrier layer 22 from a top surface of the interlayered insulating layer 3 and to form the lower electrode BE and the first insulating gap-fill pattern 26 in the selection device hole 5. The exposed top portion of the diffusion barrier layer 22 may be recessed to form the second insulating gap-fill pattern 24 that is in direct contact with a top surface of the diffusion barrier layer 22.

Subsequently, as described with reference to FIGS. 3B and 3C, the variable resistance layer 11 and a conductive layer may be sequentially stacked on the substrate 1, and patterning to form the variable resistance pattern 11 and the bit line BL.

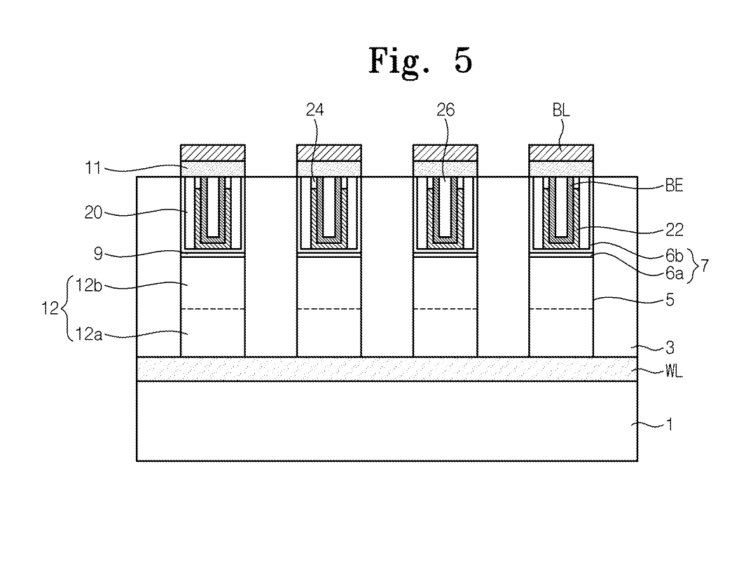

FIG. 5 is a sectional view taken along line A-A of FIG. 3B to describe a semiconductor device according to example embodiments of inventive concepts.

Referring to FIG. 5, in the variable resistance memory device according to the present example embodiments, the barrier-lowering portion 7 may include the high-k dielectric 6b and the thermal oxide layer 6a, like that of the example embodiments shown in FIG. 2. The high-k dielectric 6b may extend to be interposed between an inner sidewall of the selection device hole 5 and the insulating spacer 20. Except for this difference, the device may be configured to have substantially the same or similar features as those of FIGS. 2 and 3A-3C.

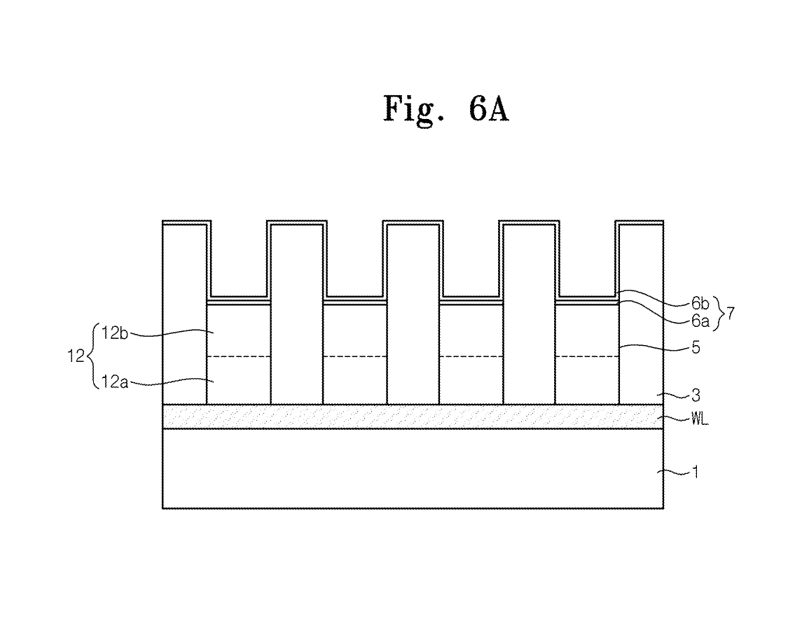

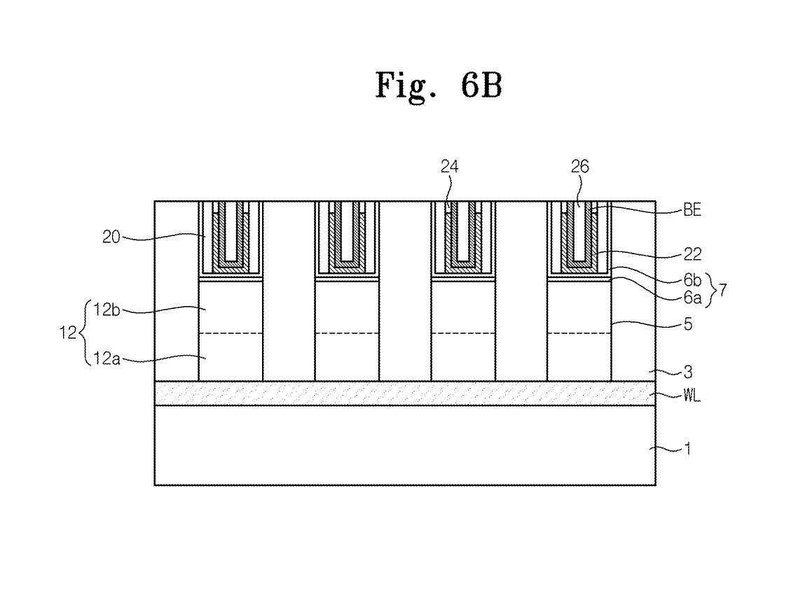

FIGS. 6A and 6B are sectional views illustrating a process of fabricating a semiconductor device having a section shaped like the example embodiments shown in FIG. 5.

Referring to FIG. 6A, the high-k dielectric 6b may be conformally deposited on the structure of FIG. 4A. Oxygen may be supplied at the high temperature for depositing the high-k dielectric 6b, and the oxygen at the high temperature may be reacted with a surface of the second semiconductor layer 12b to form the thermal oxide layer 6a.

Referring to FIG. 6B, after the formation of the high-k dielectric 6b, the insulating spacer 20 may be formed to cover an inner sidewall of the high-k dielectric 6b. Thereafter, the subsequent process may be performed in the same or similar manner as that shown in FIGS. 3A-3C.

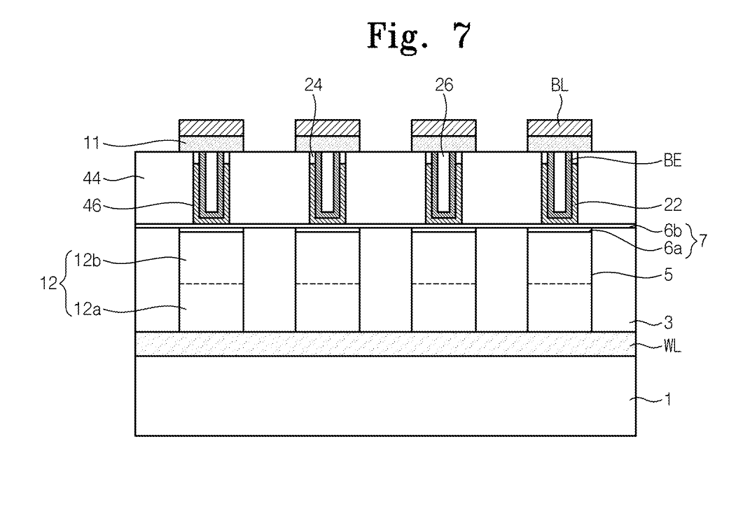

FIG. 7 is a sectional view taken along line A-A of FIG. 3B to describe a semiconductor device according to example embodiments of inventive concepts.

Referring to FIG. 7, the variable resistance memory device according to the present example embodiments may include the first interlayered insulating layer 3 and a second interlayered insulating layer 44 that are sequentially stacked on the substrate 1. The selection device hole 5 may be formed in the first interlayered insulating layer 3, and the selection device 12 may be formed in the selection device hole 5. A lower electrode hole 46 may be formed in the second interlayered insulating layer 44, and the diffusion barrier layer 22, the lower electrode BE, and the first and second insulating gap-fill patterns 26 and 24 may be provided in the lower electrode hole 46. The barrier-lowering portion 7 may be disposed between the diffusion barrier layer 22 and the second semiconductor layer 12b. The high-k dielectric 6b of the barrier-lowering portion 7 may extend to be interposed between the first and second interlayered insulating layers 3 and 44. Except for this difference, the device may be configured to have substantially the same or similar features as that shown in FIG. 5.

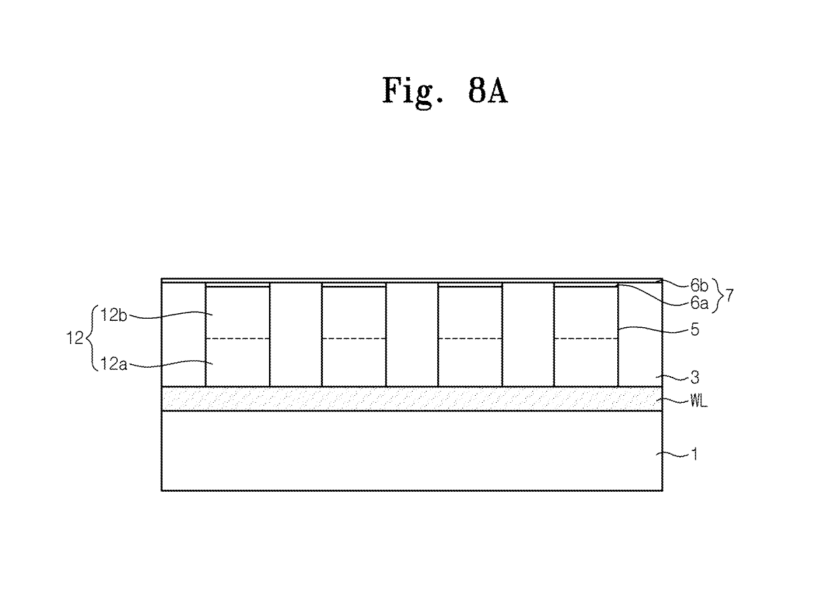

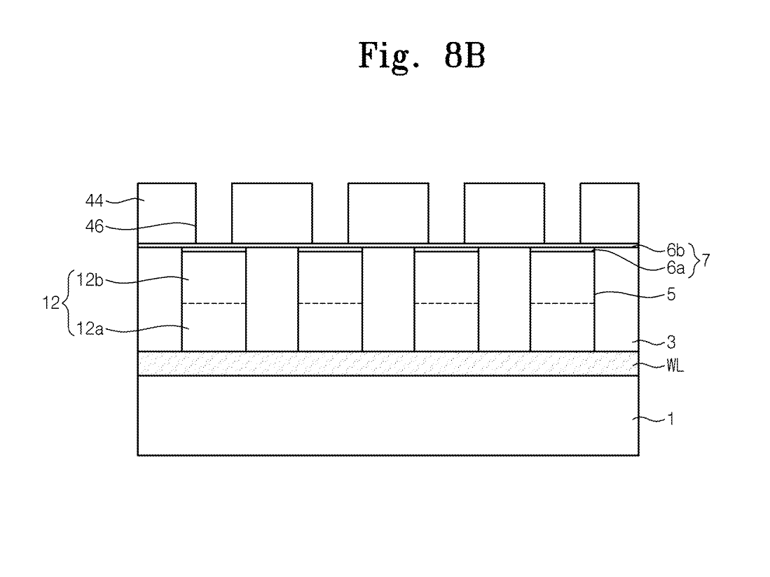

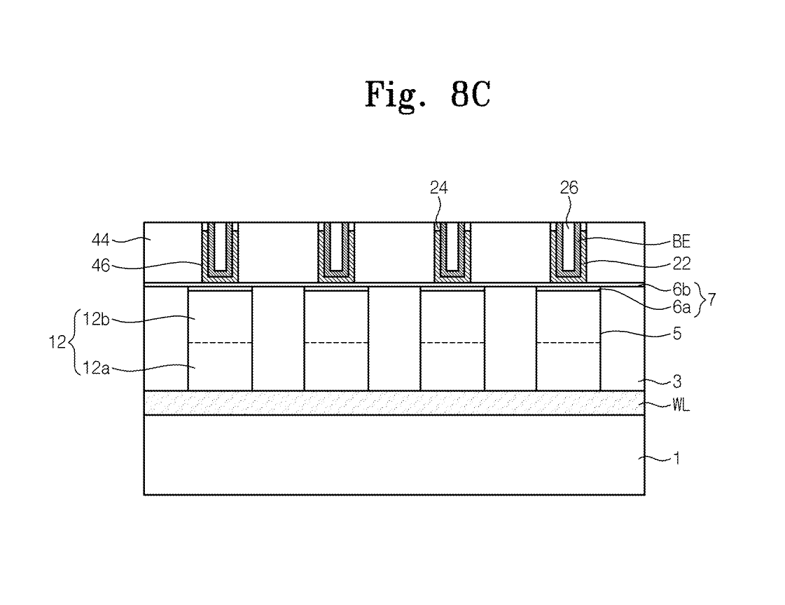

FIGS. 8A through 8C are sectional views illustrating a process of fabricating a semiconductor device having a section shaped like the example embodiments shown in FIG. 7.

Referring to FIG. 8A, the substrate 1 of, for example, P-type may be provided. The device isolation layer (not shown) may be formed in the substrate 1 to define line-shaped active regions. A first ion implantation process may be performed to dope an exposed portion of the active region with, for example, N-type impurities and thereby form the word lines WL. The first interlayered insulating layer 3 may be deposited on the substrate 1 and be patterned to form a plurality of selection device holes 5 that are spaced apart from each other. The selection device holes 5 may be formed to expose the word line WL. A selective epitaxial growth (SEG) process may be performed to form a semiconductor layer filling the selection device hole 5. A second ion implantation process may be performed to dope a lower portion of the semiconductor layer with, for example, N-type impurities and thereby form the first semiconductor layer 12a. A third ion implantation process may be performed to dope an upper portion of the semiconductor layer with, for example, P-type impurities and thereby form the second semiconductor layer 12b. The second semiconductor layer 12b may have a top surface that is substantially coplanar with that of the first interlayered insulating layer 3. The high-k dielectric 6b may be formed on the structure with the second semiconductor layer 12b. In example embodiments, the high-k dielectric 6b may be formed to cover wholly a top surface of the first interlayered insulating layer 3. Like that shown in FIG. 2, before the formation of the high-k dielectric 6b, the thermal oxide layer 6a may be formed between the high-k dielectric 6b and the second semiconductor layer 12b.

Referring to FIG. 8B, the second interlayered insulating layer 44 may be formed on the high-k dielectric 6b and be patterned to form the lower electrode hole 46. The lower electrode hole 46 may be formed on (e.g., to be overlapped with) the selection device 12. Further, the lower electrode hole 46 may be formed to have a width smaller than that of the selection device 12.

Referring to FIG. 8C, the diffusion barrier layer 22 and the lower electrode layer BE may be formed to conformally cover an inner surface of the lower electrode hole 46, and the first insulating gap fill layer 26 may be formed to fill the remaining space of the lower electrode hole 46. A planarization etching process may be performed to remove the diffusion barrier layer 22, the lower electrode layer BE, and the first insulating gap fill layer 26 from a top surface of the second interlayered insulating layer 44 and thereby form the lower electrode BE and the first insulating gap-fill pattern 26 in the lower electrode hole 46. An upper portion of the diffusion barrier layer 22 may be partially recessed, and the second insulating gap-fill pattern 24 may be formed in the recessed region.

Thereafter, the subsequent process may be performed in the same or similar manner as that shown in FIGS. 3A-3C.

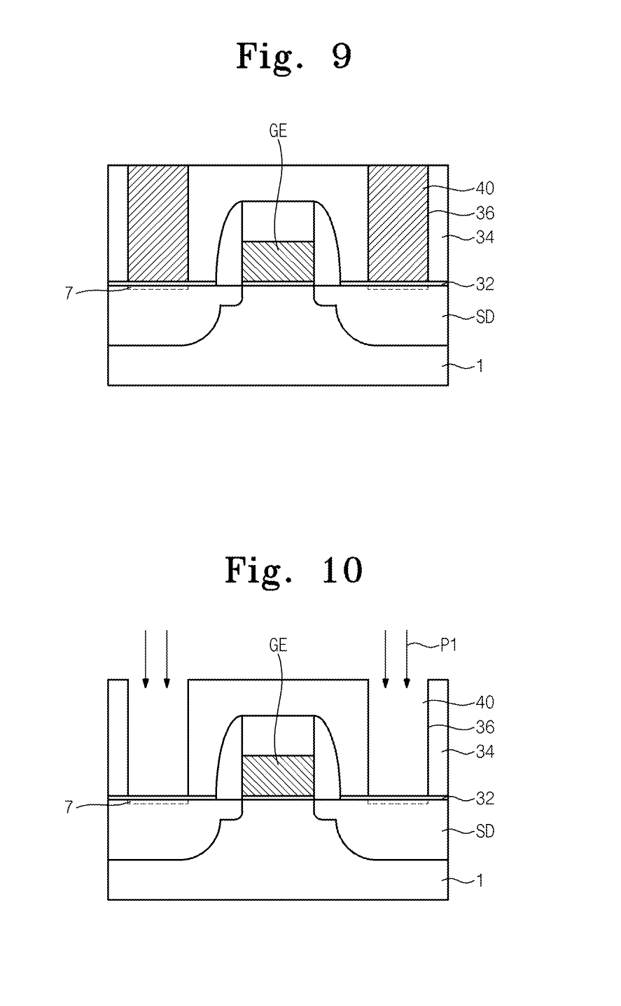

FIG. 9 is a sectional view illustrating a semiconductor device according to example embodiments of inventive concepts.

Referring to FIG. 9, the semiconductor device according to the present example embodiments may include a gate electrode GE provided on the substrate 1. The substrate 1 may be doped with, for example, N-type impurities. Source/drain regions SD may be provided in the substrate 1 adjacent to the gate electrode GE. The source/drain regions SD may be doped with, for example, P-type impurities. In example embodiments, the source/drain regions SD and the gate electrode GE may constitute a PMOSFET. A metal silicide layer 32 may be provided on the source/drain region SD. The metal silicide layer 32 and the gate electrode GE may be covered with an interlayered insulating layer 34. A contact hole 36 may be formed through the interlayered insulating layer 34. A contact plug 40 may be provided in the contact hole 36 to be in contact with the metal silicide layer 32, which may be provided on the source/drain region SD. The contact plug 40 may be formed of, for example, tungsten. The contact plug 40 may further include a diffusion barrier layer (e.g., of titanium nitride). The barrier-lowering portion 7 may be disposed between the metal silicide layer 32 and the source/drain region SD. The barrier-lowering portion 7 may have a width that is smaller than that of the metal silicide layer 32 and is equivalent or similar to that of the contact hole 36. Similar to the barrier-lowering portion 7 shown in FIG. 1, the barrier-lowering portion 7 may be formed by doping top surfaces of the source/drain regions SD with at least one element selected from the group consisting of boron, aluminum, gallium, beryllium, fluorine, and platinum. Except for this difference, the device may be configured to have substantially the same or similar features as that shown in FIG. 1.

FIG. 10 is a sectional view illustrating a process of fabricating a semiconductor device having a section shaped like the example embodiments shown in FIG. 9.

Referring to FIG. 10, the substrate 1 may be doped with, for example, N-type impurities. Agate insulating layer, the gate electrode GE, and a capping pattern may be formed on the substrate 1. In example embodiments, P-type impurities may be doped into portions of the substrate 1 located at both sides of the gate electrode GE, thereby forming the source/drain regions SD. A spacer may be formed on sidewalls of the gate electrode GE. A metal layer may be conformally formed on the substrate 1 and thermally treated to form the metal silicide layer 32 on the source/drain region SD. An unreacted portion of the metal layer may be removed. The interlayered insulating layer 34 may be formed on the structure with the metal silicide layer 32 and patterned to form the contact hole 36 exposing the metal silicide layer 32 on the source/drain regions SD. An ion implantation process P1 may be performed to form the barrier-lowering portion 7 under the metal silicide layer. In example embodiments, at least one element selected from the group consisting of boron, aluminum, gallium, beryllium, fluorine, and platinum may be used for the ion implantation process P1.

Thereafter, as shown in FIG. 9, the contact plugs 40 may be formed to fill the contact hole 36. Except for this difference, the device may be configured to have substantially the same or similar features as that shown in FIG. 1.

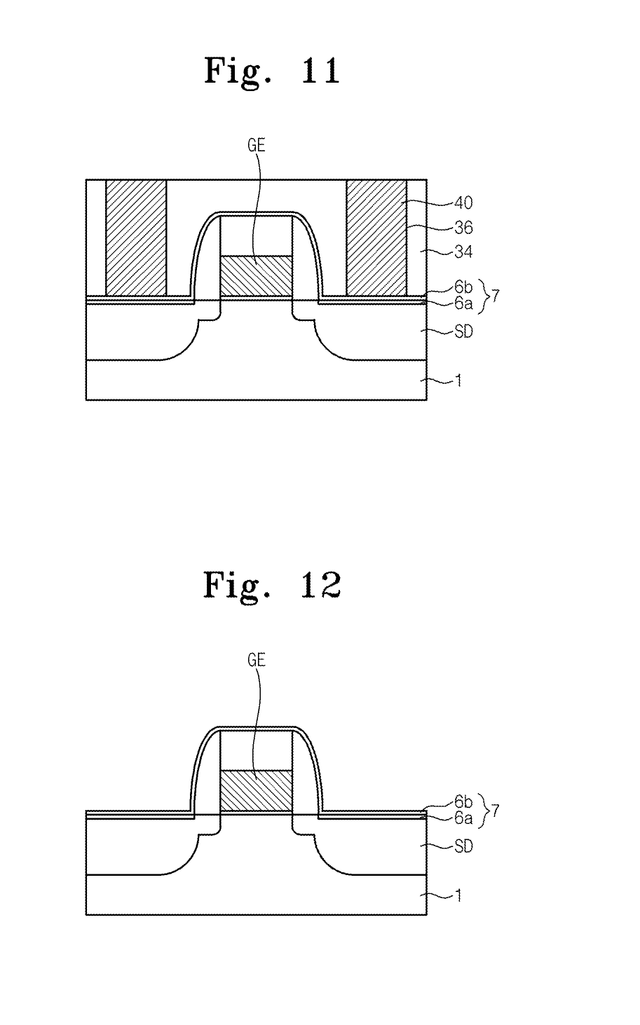

FIG. 11 is a sectional view illustrating a semiconductor device according to example embodiments of inventive concepts.

Referring to FIG. 11, the semiconductor device according to the present example embodiments may include the gate electrode GE provided on the substrate 1. The substrate 1 may be doped with, for example, N-type impurities. Source/drain regions SD may be provided in the substrate 1 adjacent to the gate electrode GE. The source/drain regions SD may be doped with, for example, P-type impurities. In example embodiments, the source/drain regions SD and the gate electrode GE may constitute a PMOSFET. The source/drain region SD and the gate electrode GE may be covered with the interlayered insulating layer 34. The contact hole 36 may be formed through the interlayered insulating layer 34. The contact plug 40 may be provided in the contact hole 36 and thereby be in contact with the metal silicide layer 32, which may be provided on the source/drain region SD. The contact plug 40 may be formed of, for example, tungsten. The contact plug 40 may further include the diffusion barrier layer (e.g., of titanium nitride). The barrier-lowering portion 7 may be disposed between the contact plug 40 and the source/drain region SD. The barrier-lowering portion 7 may include the high-k dielectric 6b and the thermal oxide layer 6a. The thermal oxide layer 6a may have a width that is greater than that of the contact hole 36. For example, the thermal oxide layer 6a may extend to cover the whole top surface of each of the source/drain regions SD. The high-k dielectric 6b may extend to cover the gate electrode GE. Except for this difference, the device may be configured to have substantially the same or similar features as that shown in FIG. 2.

FIG. 12 is a sectional view illustrating a process of fabricating a semiconductor device having a section shaped like the example embodiments shown in FIG. 11.

Referring to FIG. 12, the substrate 1 may be doped with, for example, N-type impurities. The gate insulating layer, the gate electrode GE, and the capping pattern may be formed on the substrate 1. In example embodiments, P-type impurities may be doped into portions of the substrate 1 located at both sides of the gate electrode GE, thereby forming the source/drain regions SD. The spacers may be formed on sidewalls of the gate electrode GE. The high-k dielectric 6b may be conformally formed on the structure with the spacers. In example embodiments, the thermal oxide layer 6a may be formed between the high-k dielectric 6b and the source/drain region SD. The high-k dielectric 6b may be formed to cover the gate electrode GE.

Thereafter, as shown in FIG. 11, the interlayered insulating layer 34 may be provided on the high-k dielectric 6a and patterned to form the contact hole 36. The contact plug 40 may be formed to fill the contact hole 36.

Except for this difference, the process may be performed in the same or similar manner as that shown in FIG. 2.

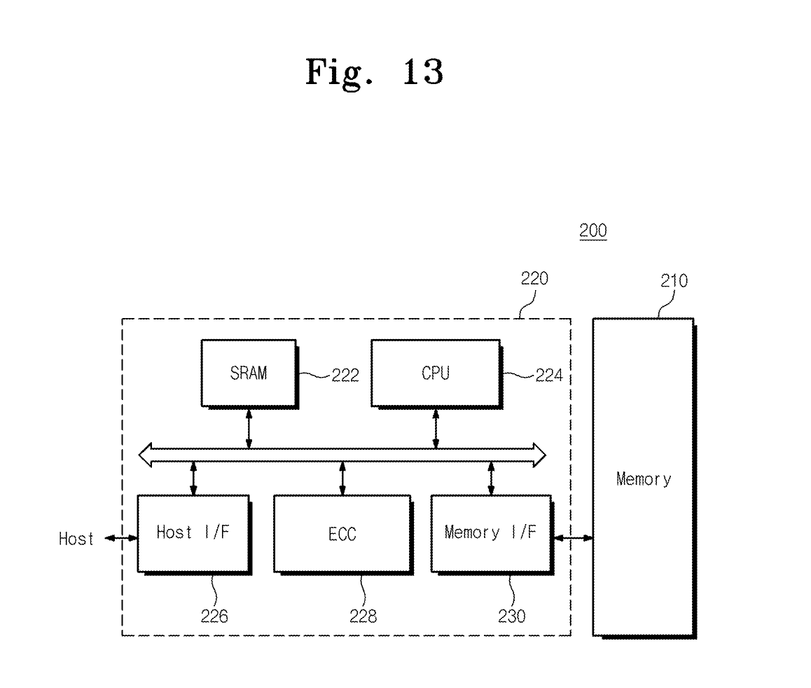

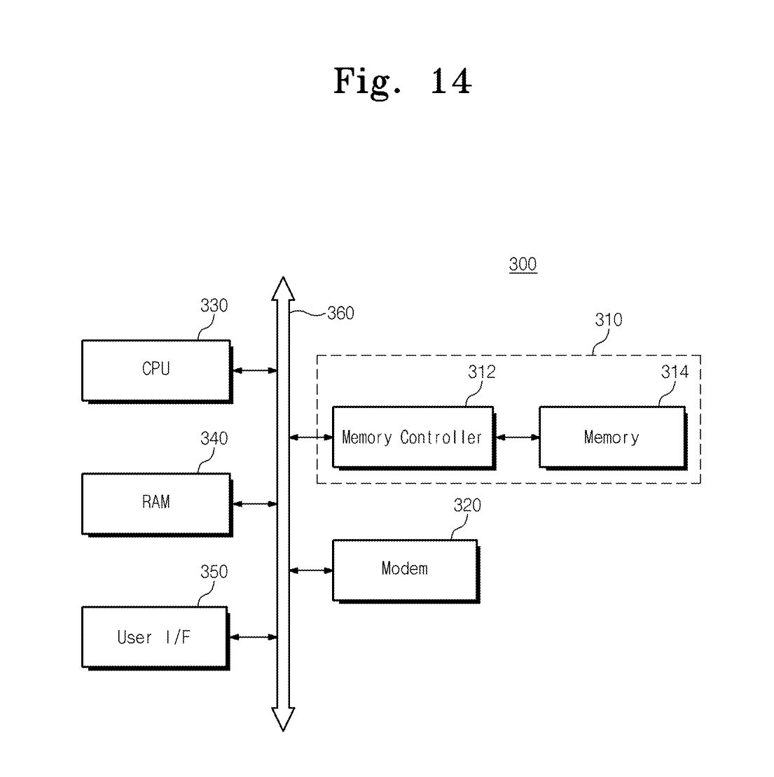

FIG. 13 is a block diagram illustrating an example of systems including a memory device according to example embodiments of inventive concepts.

Referring to FIG. 13, the system may be a memory card 200 including at least one of the variable resistance memory devices according to example embodiments of inventive concepts. For instance, the memory card 200 may include a memory controller 220 controlling general data exchanges between a host and a memory device 210. A static random access memory (SRAM) 222 may be used as an operating memory of a processing unit 224. A host interface 226 may include a data exchange protocol of a host connected to the memory card 200. An error correction code 228 may detect and correct errors included in data read from the memory device 210. A memory interface 230 may interface with the memory device 210. A processing unit 224 may perform general control operations for data exchange of the memory controller 220.

The memory device 210 may be one of the variable resistance memory devices according to example embodiments of inventive concepts. Accordingly, the memory device 210 may include an ohmic pattern and a first electrode pattern aligned with each other in a self-alignment manner, and the fabricating method thereof can be simplified. In addition, the memory device 210 may include a selection device having a height substantially lower than that of a conventional selection device. Accordingly, the memory device 210 can be easily fabricated.

FIG. 14 is a block diagram illustrating an example of memory cards including a memory device according to example embodiments of inventive concepts.

Referring to FIG. 14, the in Formation processing system 300 may be realized using a memory system 310 including at least one of the variable resistance memory devices according to example embodiments of inventive concepts. For instance, the in Formation processing system 300 may be a mobile device and/or a desktop computer. In some example embodiments, the in Formation processing system 300 may further include a modem 320, a central processing unit (CPU) 330, a RAM 340, and a user interface 350, which are electrically connected to a system bus 360, in addition to the memory system 310. Data processed by the CPU 330 and/or input from the outside may be stored in the memory system 310. The memory system 310 may include a memory device 312 and a memory controller 314, and in some example embodiments, the memory system 310 may be configured substantially identical to the system described with respect to FIG. 14. Although not illustrated, it is apparent to those skilled in the art that, for example, a memory card, a solid state drive (SSD), an application chipset, a camera image sensor, a camera image signal processor (ISP), an input/output device, or the like may further be included in the in Formation processing system 300 according to inventive concepts. In some example embodiments, the memory system 310 may be used as a portion of the solid state drive (SSD), and in this case, the in Formation processing system 300 may stably and reliably store a large amount of data in the memory system 310.

According to example embodiments of inventive concepts, the semiconductor device may include a barrier-lowering portion interposed between a metal-containing layer and a semiconductor layer, and thus, a Schottky barrier height may be lowered between the metal-containing layer and the semiconductor layer than between a metal silicide layer and the semiconductor layer, for example, in direct contact with each other. For example, the barrier-lowering portion may lower a Schottky barrier height between the semiconductor layer and the metal-containing layer to 0.6 eV or less. Accordingly, it is possible to improve a current flow (e.g., on-current) between the metal-containing layer and the semiconductor layer, and this makes it possible to improve an operation speed of the device.

While example embodiments of inventive concepts have been particularly shown and described, it will be understood by one of ordinary skill in the art that variations in form and detail may be made therein without departing from the spirit and scope of the attached claims.

What is claimed is:

1. A semiconductor device, comprising:
a metal-containing layer on a semiconductor layer; and
a barrier-lowering portion between the semiconductor layer and the metal-containing layer,
wherein the barrier-lowering portion lowers a Schottky barrier height (SBH) between the metal-containing layer and the semiconductor layer below an SBH between a metal silicide layer and the semiconductor layer.

2. The device of claim 1, wherein the semiconductor layer is doped with P-type impurities and has an impurity concentration of 10²⁰ ions/cm³ or higher.

3. The device of claim 1, wherein the barrier-lowering portion includes a dopant within a surface of the semiconductor layer, and
the dopant includes at least one element selected from the group consisting of aluminum, gallium, beryllium, fluorine, and platinum.

4. The device of claim 3, wherein a concentration of the at least one element ranges from about 10¹⁹ atoms/cm³ to about 10²⁰ atoms/cm³.

5. The device of claim 3, further comprising:
a metal silicide layer between the barrier-lowering portion and the metal-containing layer.

6. The device of claim 1, wherein the barrier-lowering portion includes a high-k dielectric material, and
the high-k dielectric material has a dielectric constant higher than a dielectric constant of silicon oxide.

7. The device of claim 6, wherein the barrier-lowering portion further includes a thermal oxide layer between the high-k dielectric material and the semiconductor layer.

8. The device of claim 7, wherein the thermal oxide layer has a thickness of about 5-10 Å.

9. The device of claim 6, wherein the high-k dielectric material is formed of aluminum oxide and has a thickness of 10 Å or less.

10. The device of claim 6, wherein the high-k dielectric material is formed of titanium oxide and has a thickness of 60 Å or less.

11. The device of claim 1, further comprising:
a substrate below the semiconductor layer;
a word line within the substrate;
a bit line on the metal-containing layer and crossing the word line; and
a variable resistance pattern between the metal-containing layer and the bit line,
wherein the semiconductor layer is configured to form a pn-junction diode between the word line and the metal-containing layer.

12. The device of claim 11, further comprising:
a first interlayered insulating layer covering the substrate and including a first hole,
wherein the semiconductor layer, the barrier-lowering portion, and the metal-containing layer are within the first hole, and
the barrier-lowering portion includes a high-k dielectric extending along an inner sidewall of the first hole.

13. The device of claim 11, further comprising:
a first interlayered insulating layer covering the substrate; and
a second interlayered insulating layer on the first interlayered insulating layer,
wherein the semiconductor layer and the metal-containing layer are within the first and second interlayered insulating layers, respectively, and
the barrier-lowering portion includes a high-k dielectric extending between the first and second interlayered insulating layers.

14. The device of claim 1, further comprising:
a gate electrode on the semiconductor layer; and
a metal silicide layer between the metal-containing layer and the semiconductor layer,
wherein the semiconductor layer is a semiconductor substrate,
the metal-containing layer corresponds to a contact plug adjacent to the gate electrode,
the barrier-lowering portion includes a dopant within a surface of the semiconductor layer, and
the dopant includes at least one element selected from the group consisting of boron, aluminum, gallium, beryllium, fluorine, and platinum.

15. The device of claim 1, further comprising:
a gate electrode on the semiconductor layer,
wherein the semiconductor layer is a semiconductor substrate,
the metal-containing layer corresponds to a contact plug adjacent to the gate electrode, and
the barrier-lowering portion includes a high-k dielectric extending to cover the gate electrode.

16. A semiconductor device, comprising:
a Schottky barrier contact including a barrier-lowering portion crossing the Schottky barrier contact along a metal-semiconductor junction of the Schottky barrier contact,
wherein the barrier-lowering portion reduces a Schottky barrier height (SBH) of the metal-semiconductor junction to lower than about 0.6 eV.

17. The semiconductor device of claim 16, further comprising:
an ohmic layer between the barrier-lowering portion and a metal-containing layer of the Schottky barrier contact,
wherein the ohmic layer includes a metal silicide,
the metal-containing layer includes a metal nitride, and
the barrier-lowering portion includes at least one selected from an aluminum dopant, a gallium dopant, a beryllium dopant, a fluorine dopant and a platinum dopant.

18. The semiconductor device of claim 16, further comprising:
a gate electrode on a substrate, wherein the barrier-lowering portion is at least partially recessed within an interlayered insulating layer over the substrate;
a source and drain region in the substrate adjacent to the gate electrode;
a contact plug over the source and drain region; and
an ohmic layer in contact with the contact plug,
wherein the barrier-lowering portion is under the contact plug and has a width greater than or equal to a width of the contact plug, and
the Schottky barrier contact collectively includes the source and drain region, the barrier-lowering portion, the contact plug, and the ohmic layer.

19. The semiconductor device of claim 16, wherein the barrier-lowering portion consists of a high dielectric layer over a thermal oxide layer.

20. The semiconductor device of claim 16, wherein,
the Schottky barrier contact further includes a diffusion barrier layer and a semiconductor layer, collectively, forming the metal-semiconductor junction,
the diffusion barrier layer is a metal nitride layer, and
the barrier-lowering portion includes a dopant made of at least one element selected from the group consisting of aluminum, gallium, beryllium, fluorine, and platinum.
